(19) United States
(12) Patent Application Publication
(10) Pub. No.: US 2014/0354351 A1
(43) Pub. Date: Dec. 4, 2014

(54) CHOPPING CIRCUIT FOR MULTIPLE OUTPUT CURRENTS

(71) Applicant: CIREL SYSTEMS PRIVATE LIMITED, Bangalore (IN)

(72) Inventors: Abhilasha KAWLE, Bangalore (IN); Rachit RAWAT, Bangalore (IN); Shyam SUBRAMANIAN, Bangalore (IN); Prakash EASWARAN, Bangalore (IN); Sundararajan KRISHNAN, Bangalore (IN)

(73) Assignee: CIREL SYSTEMS PRIVATE LIMITED, Bangalore (IN)

(21) Appl. No.: 14/286,185

(22) Filed: May 23, 2014

(30) Foreign Application Priority Data
Jun. 3, 2013 (IN) 2406/CHE/2013

(51) Int. Cl. H03K 17/687

(52) U.S. Cl. CPC H03K 17/6871; H03K 2217/94
USPC 327/581

(57) ABSTRACT

A circuit for reducing flicker noise includes a first current source coupled to an input current. The circuit includes current minors to generate output currents in response to the input current. The output currents include the flicker noise. In addition, the circuit includes a chopping circuit to reduce the flicker noise from each of the output currents.

### TECHNICAL FIELD

Embodiments of the disclosure relate generally to circuits employing multiple current sources, and more specifically to reducing low frequency noise in circuits employing multiple current sources.

### BACKGROUND

Typically, a current source can be implemented using metal oxide semiconductor field effect transistors (MOSFETs) operating in saturation region. Often, a current minor circuit employs a MOSFET based current source to produce an output current.

FIG. 1 illustrates a basic MOSFET current minor circuit, hereinafter referred to as circuit 100. The circuit 100 includes a first MOS transistor 105 and a second MOS transistor 110. The first MOS transistor 105 has drain and gate terminals shorted together. The drain and gate terminals when shorted, pushes the first MOS transistor 105 to operate in saturation mode, if drain current I_{D1}≠0. In the circuit 100, source terminals of the first MOS transistor 105 and the second MOS transistor 110 are connected together and therefore the first MOS transistor 105 and the second MOS transistor 110 will have identical gate-source voltage, V_{GS}. If the first MOS transistor 105 is identical to the second MOS transistor 110, the second MOS transistor 110 acts as a current sink.

Typically, MOSFET devices suffer from various low frequency noises, for example, flicker noise. Flicker noise or 1/f noise is mainly caused by defects in interface between gate oxide and silicon substrate. The flicker noise is often characterized by corner frequency fc, between region dominated by low-frequency flicker noise and higher frequency “flat-band” noise. MOSFETs have a higher corner frequency fc in the GHz range and hence flicker noise is more prominent in MOSFETs than in junction field effect transistors (JFET) or bipolar transistors. Flicker noise can be reduced by conventional methods which include chopping. Chopping is a continuous time modulation technique in which the signal and noise is modulated to different frequencies.

FIG. 2 illustrates a circuit 200 that employs chopping for reducing flicker noise. The circuit 200 includes a first chopper circuit 205, a second chopper circuit 210, an operational amplifier 215, and a low pass filter (LPF) 220. An input signal Vᵢₙ is first passed through the chopper circuit 205, driven by a clock frequency f_{ch}, where it is modulated to frequencies around clock frequency f_{ch} Modulated signal is amplified together with its own input offset voltage by the operation amplifier 215. The second chopper circuit 210, then demodulates the amplified input signal back to input signal, and at the same time modulates the offset voltage and the flicker noise to odd harmonics of the clock frequency f_{ch}. The offset and the flicker noise are then filtered by the low pass filter 220, which results in an amplified output without offset and flicker noise. To completely reduce the flicker noise, the chopping frequency should be higher than the 1/f noise corner frequency. Chopping can be implemented in current circuits also.

FIG. 3 illustrates a MOSFET based current mirror circuit 300 that employs chopping. The circuit 300 includes a current minor 305. The current minor 305 further includes a chopping circuit 315. The chopping circuit 315 receives a chopping (CHOP) signal, having a chopping frequency f_{chop}. The chopping circuit 315 modulates current and errors to the chopping frequency f_{chop}. However, the chopping circuit 315 is implemented for the current minor circuit 305 with a single input and single output. Though, the circuit 300 depicted in FIG. 3 does not pose any inherent limitations, certain applications require multiple current outputs. For example, multiple current outputs can be used to drive electronic circuits like digital to analog converter (DAC). However, multiple single-input single-output current mirrors results in wastage of power.

In the light of the foregoing discussion, there is a need for reducing the flicker noise in a MOSFET current minor circuit having multiple current outputs.

### SUMMARY

The above-mentioned needs are met by employing a chopping circuit in a MOSFET current minor circuit having multiple current outputs.

An example of a circuit for reducing flicker noise includes a first current source coupled to an input current. The circuit includes current minors to generate output currents in response to the input current. The output currents include the flicker noise. In addition, the circuit includes a chopping circuit to reduce the flicker noise from each of the output currents.

An example of a method of reducing flicker noise in a current minor circuit comprising output currents includes electrically coupling an input current to metal oxide semiconductor field effect transistors. The method includes generating the output currents in response to the coupling. The output currents area function of the input current and the flicker noise of at least two of the metal oxide semiconductor field effect transistors. Further, the method includes calculating average of the output currents to reduce the flicker noise.

An example of a circuit for reducing flicker noise includes a first metal oxide semiconductor field effect transistor (MOSFET) coupled to an input current. The circuit includes a second MOSFET to generate a first output current. The circuit includes a third MOSFET to generate a second output current. The circuit includes a fourth MOSFET to generate a third output current. In addition, the circuit includes a four phase chopping circuit including a plurality of switches. At least four switches are operational at each phase.

The features and advantages described in this summary and in the following detailed description are not all-inclusive, and particularly, many additional features and advantages will be apparent to one of ordinary skill in the relevant art in view of the drawings, specification, and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE FIGURES

In the following drawings like reference numbers are used to refer to like elements. Although the following figures depict various examples of the invention, the invention is not limited to the examples depicted in the figures.

FIG. 1 illustrates a basic metal oxide semiconductor field effect transistor (MOSFET) current mirror circuit;

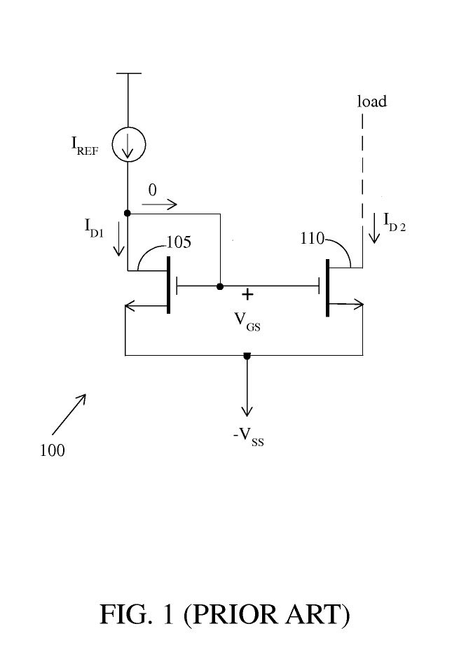

FIG. 2 illustrates a circuit that employs chopping for reducing flicker noise;

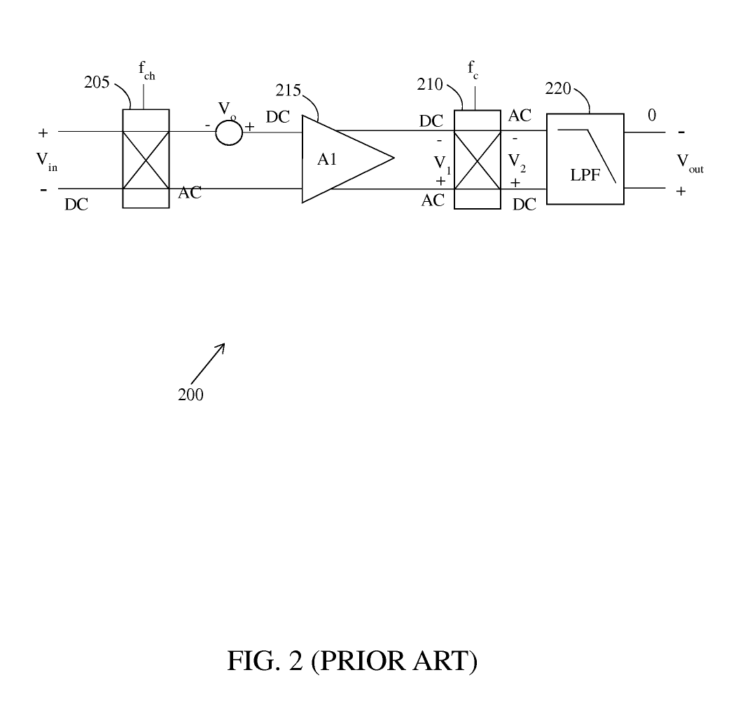

FIG. 3 illustrates a MOSFET based current mirror circuit that employs chopping;

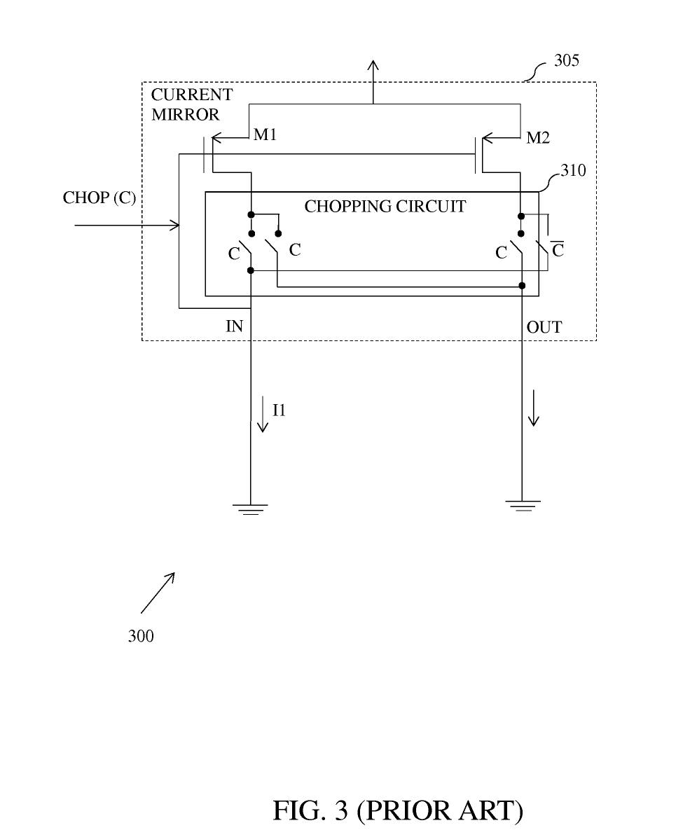

FIG. 4 is an exemplary block diagram of a circuit for a multiple output current minor that reducing flicker noise by employing chopping, in accordance with one embodiment of the present disclosure;

FIG. 5 illustrates a circuit having multiple output currents that employs chopping for reducing flicker noise, in accordance to another embodiment of the present disclosure;

FIG. 5A is an exemplary illustration of one of the states of the circuit having multiple output currents that employs chopping for reducing flicker noise, in accordance with one yet another embodiment of the present disclosure;

FIG. 5B is an exemplary illustration of one of the states of the circuit having multiple output currents that employs chopping for reducing flicker noise, in accordance with one embodiment of the present disclosure;

FIG. 5C is an exemplary illustration of one of the states of the circuit having multiple output currents that employs chopping for reducing flicker noise, in accordance with another embodiment of the present disclosure;

FIG. 5D is an exemplary illustration of one of the states of the circuit having multiple output currents that employs chopping for reducing flicker noise, in accordance with yet another embodiment of the present disclosure;

FIG. 6 illustrates a timing diagram of the clock waveforms, in 4-phase chopping scheme, in accordance with one embodiment of the present disclosure; and

FIG. 7 is a flowchart illustrating a method involved in reducing the flicker noise, in accordance with one embodiment of the present disclosure.

### DETAILED DESCRIPTION OF THE EMBODIMENTS

A circuit and method of reducing flicker noise in a metal oxide semiconductor field effect transistor (MOSFET) current mirror having multiple output currents is explained in the following description. Flicker noise can be reduced by conventional methods which include chopping. Chopping is a continuous time modulation technique, in which noise that appears in low frequency bands is modulated to a higher frequency band. After demodulation of the signal, the noise is filtered from the desired outputs using a low pass filter.

In the present disclosure, relational terms, for example first and second, can be used to distinguish one entity from the other, without necessarily implying any actual relationship or order between such entities.

The following detailed description is intended to provide example implementations to one of ordinary skill in the art, and is not intended to limit the invention to the explicit disclosure, as one or ordinary skill in the art will understand that variations can be substituted that are within the scope of the invention as described.

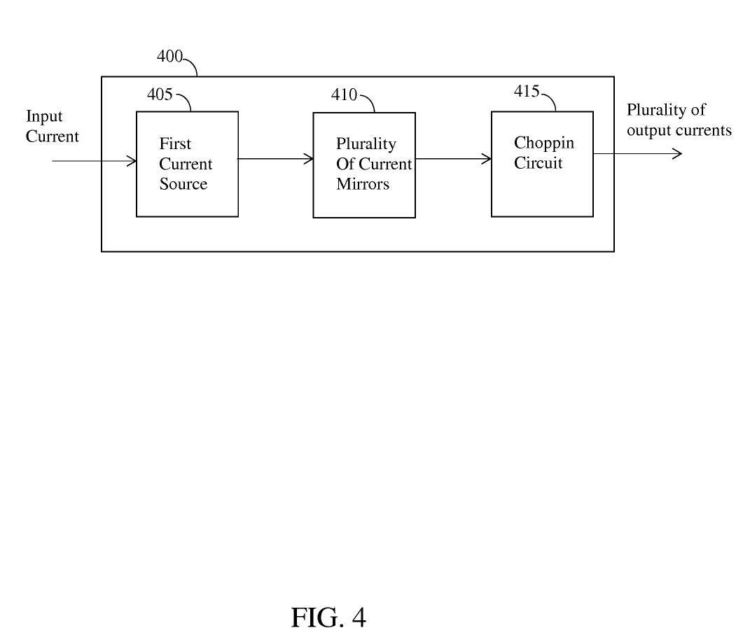

FIG. 4 is an exemplary block diagram of a circuit 400. The circuit 400 reduces flicker noise in a plurality of output currents by using a chopping scheme. The circuit 400 includes a first current source 405, a plurality of current mirrors 410, and a chopping circuit 415. The first current source 405 is a metal oxide semiconductor field effect transistor (MOSFET). In one embodiment, the first current source 405 comprises an NMOS transistor. In another embodiment, the first current source 405 comprises a PMOS transistor. The first current source comprises a gate terminal, a drain terminal, and a source terminal. The gate terminal and the drain terminal of the first current source 405 are shorted. The first current source 405 is coupled to an input current. When coupled to the input current it accepts the input current and generates the necessary gate voltage. Each of the plurality of current minors 410 is a metal oxide semiconductor transistor (MOSFET). In one embodiment, each of the plurality of current minors 410 comprises an NMOS transistor. In another embodiment, each of the plurality of current minors 410 comprises a PMOS transistor. The MOSFET introduces flicker noise which is dominant at low frequency. The plurality of current mirrors 410 produces the plurality of output currents by replicating the input current. The flicker noise affects the plurality of output currents.

The chopping circuit 415 is a four phase chopping circuit. The four phase chopping circuit operates at four different phases in one complete chopping cycle. The four phase chopping circuit includes a plurality of switches. The four phase chopping circuit includes at least four switches operational in each phase. The chopping circuit 415 reduces the flicker noise in the plurality of output currents generated. The plurality of output currents generated at each phase, is a function of the input current and the flicker noise of at least two metal oxide semiconductor field effect transistors. The low-frequency content of each of the plurality of output currents, generated in one complete chopping cycle, is obtained by averaging the components of the each output current in all the four phases. On averaging the flicker noise gets cancelled and an exact replica of the input current is produced.

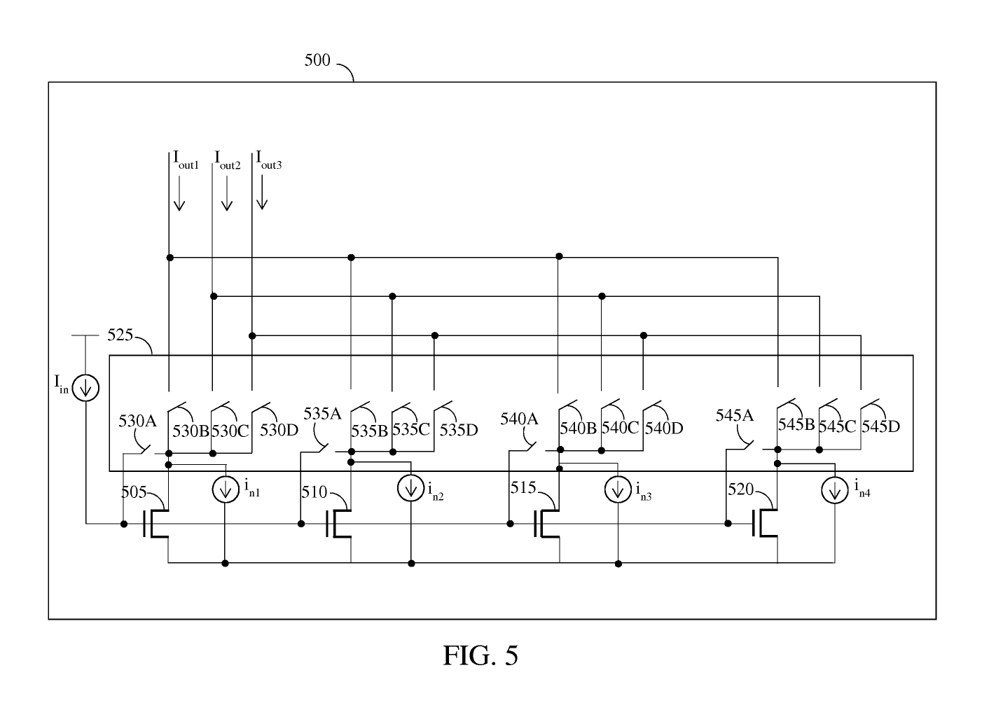

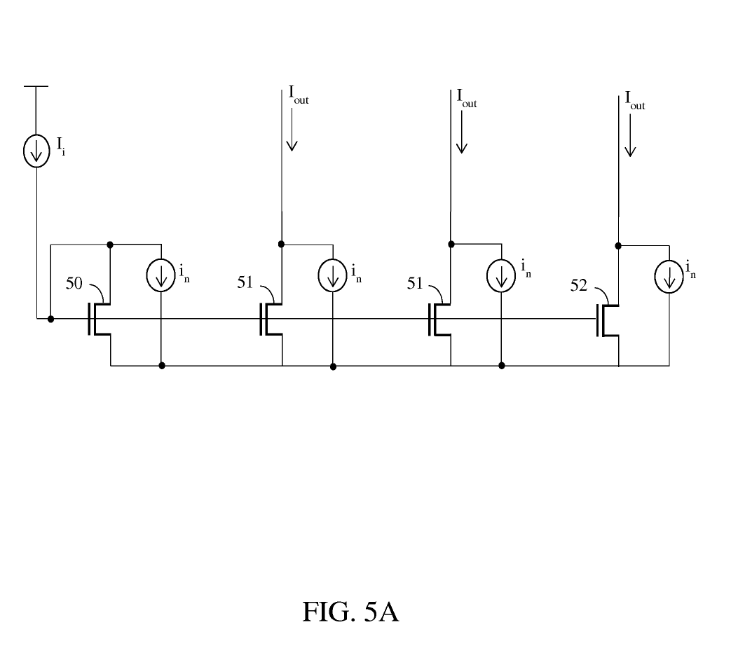

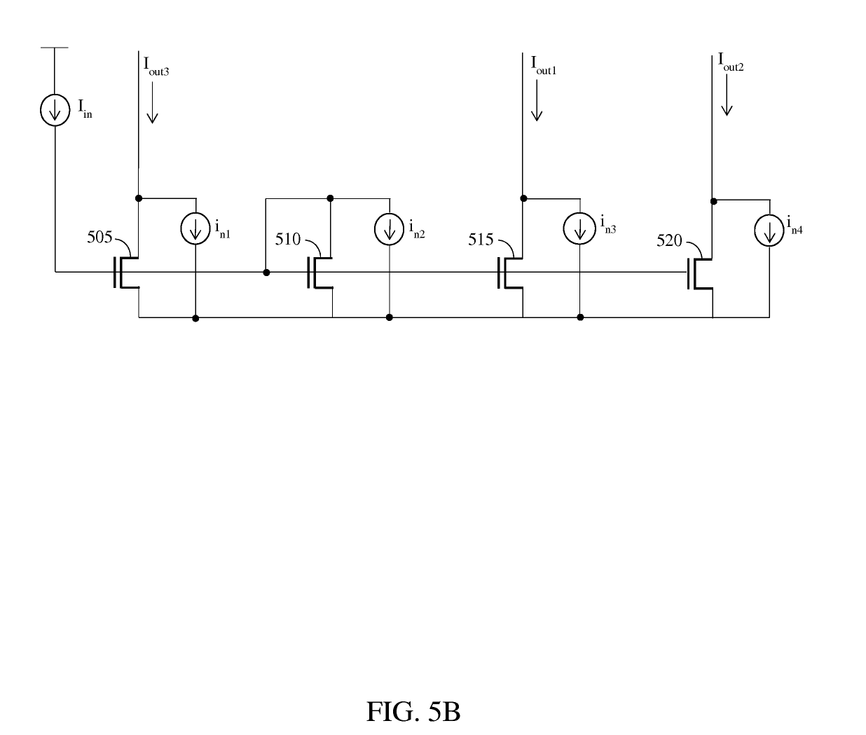

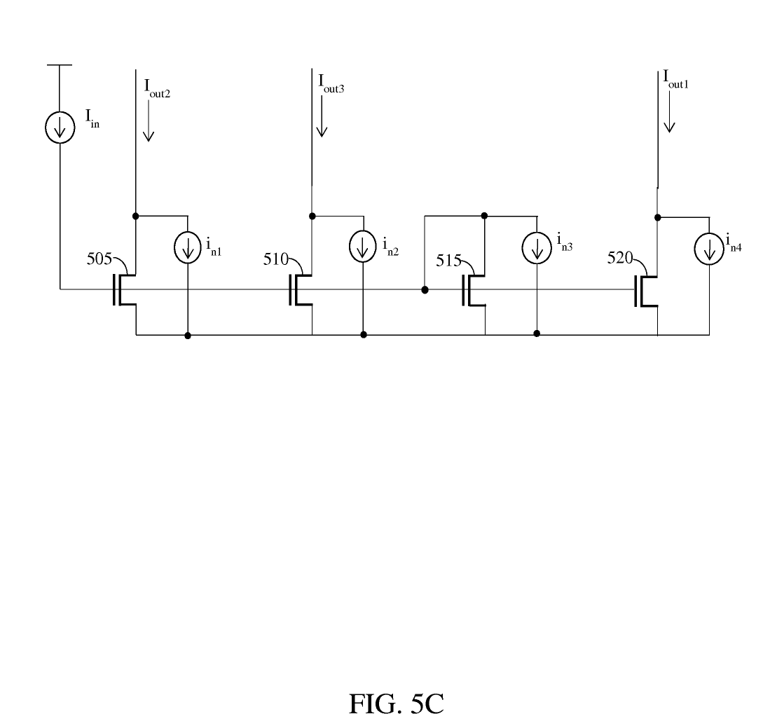

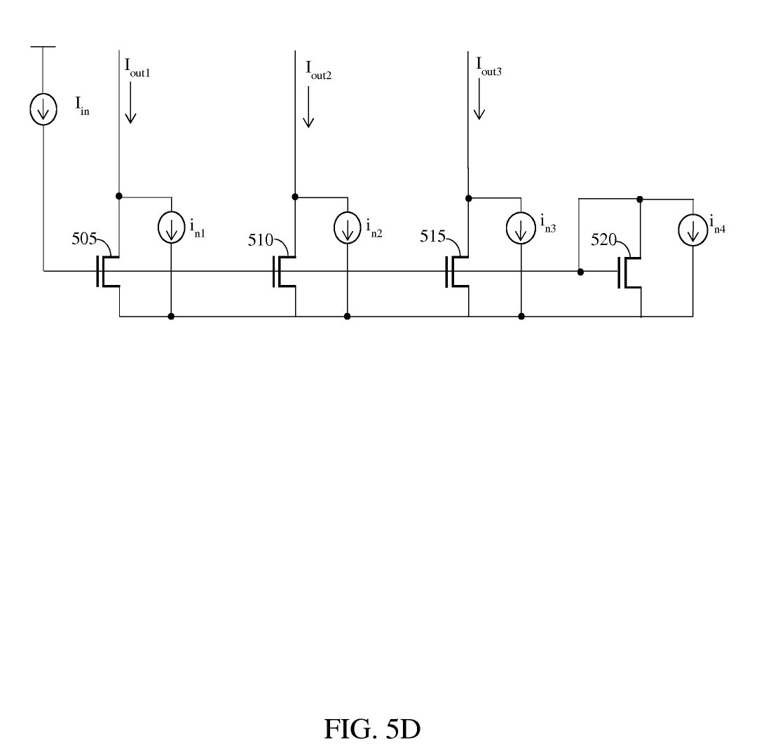

FIG. 5 illustrates a circuit 500 having multiple output currents that employs chopping for reducing flicker noise. The circuit 500 is a one input-three output current mirror circuit employing chopping.

The circuit 500 includes a first MOSFET 505, a second MOSFET 510, a third MOSFET 515, a fourth MOSFET 520, and a four phase chopping circuit 525. In one embodiment, the first MOSFET 505, the second MOSFET 510, the third MOSFET 515, and the fourth MOSFET 520 are NMOS transistors. In another embodiment, the first MOSFET 505, the second MOSFET 510, the third MOSFET 515, the fourth MOSFET 520 are PMOS transistors. The four phase chopping circuit 525 includes a plurality of switches. The plurality of switches include switch 530A, switch 530B, switch 530C, switch 530D, switch 535A, switch 535B, switch 535C, switch 535D, switch 540A, switch 540B, switch 540C, switch 540D, switch 545A, switch 545B, switch 545C, and switch 545D The switch 530A, the switch 530B, the switch 530C and the switch 530D are coupled to the first MOSFET 505. The switch 535A, the switch 535B, the switch 535C, and the switch 535D are coupled to the second MOSFET 510. The switch 540A, the switch 540B, the switch 540C, and the switch 540D are coupled to the third MOSFET 515. The switch 545A, the switch 545B, the switch 545C, and the switch 545D are coupled to the fourth MOSFET 520.

The plurality of switches can be in either CLOSED state or OPEN state. The CLOSED state and OPEN state of various switches couples an input current to the first MOSFET 505, the second MOSFET 510, the third MOSFET 515 and the fourth MOSFET 520. The first MOSFET 505, the second MOSFET 510, the third MOSFET 515 and fourth MOSFET 520 act as current sources having inherent noise in them. The first MOSFET 505 introduces a noise iₙ₁, the second MOSFET 510 introduces a noise iₙ₂, the third MOSFET 515 introduces a noise and the fourth MOSFET 520 introduces a noise iₙ₄. The noise iₙ₁, the noise iₙ₂, the noise iₙ₃ and the noise iₙ₄ are considered as flicker noise, which is dominant at low frequency. The four phase chopping circuit 525 reduces the flicker noise. The four phase chopping circuit 525 operates on four clock phases Φ₁, Φ₂, Φ₃, and Φ₄. In each phase Φ₁, Φ₂, Φ₃, and Φ₄ a group of four different switches in the plurality of switches are operational. A chopping clock frequency of the four phase chopping circuit 525 is made large enough, to make the noise iₙ₁, the noise iₙ₂, the noise iₙ₃, and the noise iₙ₄ constant across the clock phases Φ₁, Φ₂, Φ₃, and Φ₄.

Functions of the first MOSFET 505, the second MOSFET 510, the third MOSFET 515 and the fourth MOSFET 520 are interchanged in each of the four clock phases Φ₁, Φ₂, Φ₃, and Φ₄. In one phase, the first MOSFET 505 is coupled to the input current Iᵢₙ. The second MOSFET 510 generates a first output current Iₒᵤₜ₁. The third MOSFET 515 generates a second output current Iₒᵤₜ₂. Further, the fourth MOSFET 520 generates a third output current Iₒᵤₜ₃. The first MOSFET 505 in conjunction with the second MOSFET 510, the third MOSFET 515 and the fourth MOSFET 520 forms the one input-three output current minor circuit. The first output current Iₒᵤₜ₁, the second output current Iₒᵤₜ₂, and the third output current Iₒᵤₜ₃ are a function of the input current and the flicker noise of at least two metal oxide semiconductor transistors.

The four phase chopping circuit 525, when operating at different clock phases produces different current mirror outputs. The difference in output is mainly due to the flicker noise. As a result of the flicker noise, the four phase chopping circuit 525 at phase Φ₁, produces the first output current Iₒᵤₜ₁, the second output current Iₒᵤₜ₂ and the third output current Iₒᵤₜ₃ as I_{out1(Φ1)}, i_{out2 (Φ1)}, and I_{out3 (Φ1)}. Likewise, the 4-phase chopping circuit 525 at phase Φ₂, produces the first output current Iₒᵤₜ₁, the second output current Iₒᵤₜ₂ and the third output current Iₒᵤₜ₃ and Iₒᵤₜ₃ as I_{out1 (Φ2)}, I_{out2 (Φ2)}, and I_{out3 (Φ2)}. The four phase chopping circuit 525 at phase Φ₃, produces the first output current Iₒᵤₜ₁, the second output current Iₒᵤₜ₂ and the third output current Iₒᵤₜ₃ as I_{out1 (Φ3)}, I_{out2 (Φ3)}, and I_{out3 (Φ3)}. The four phase chopping circuit 525 at phase Φ₄, produces the first output current Iₒᵤₜ₁, the second output current Iₒᵤₜ₂ and the third output current Iₒᵤₜ₃ as I_{out1 (Φ4)}, I_{out2 (Φ4)}, and I_{out3 (Φ4)}. In order to find the low-frequency content of the first output current Iₒᵤₜ₁, the second output current Iₒᵤₜ₂ and the third output current Iₒᵤₜ₃, average of each current in one complete chopping cycle is calculated. The flicker noise in the circuit 500 gets cancelled on taking the average of each current output.

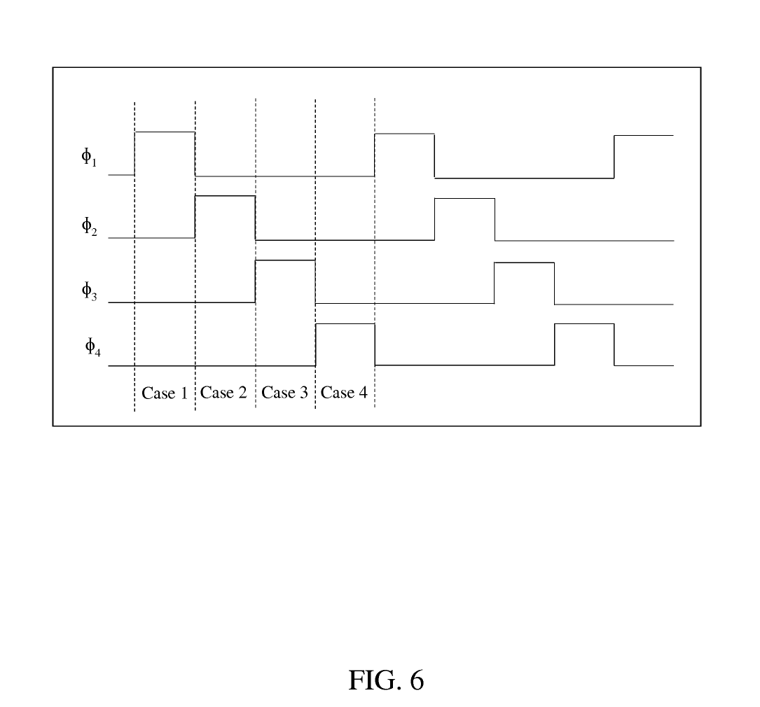

The operation of circuit 500 is further explained in conjunction with FIG. 6. FIG. 6 shows timing diagram of the clock waveforms, corresponding to clock phases Φ₁, Φ₂, Φ₃, and Φ₄ in 4-phase chopping scheme. The circuit 500 operating in each clock phase Φ₁, Φ₂, Φ₃, and Φ₄, is explained as four different cases. In each case, one of the clock phase is at level ‘1’ and the remaining clock phases are at level ‘0’. Based on level of the clock phase being ‘1’ or ‘0’, the various switches are either in the CLOSED state or in the OPEN state.

### Case 1:

FIG. 5A is an exemplary illustration of the circuit 500 operating at clock phase Φ₁. In case 1, clock phase Φ₁ is at level ‘1’ and the remaining clock phases Φ₂, Φ₃ and Φ₄ are at level ‘0’ as indicated in FIG. 6. When the clock phase Φ₁ is at level ‘1’, the switch 530A, the switch 535B, the switch 540C, and the switch 545D are in the CLOSED state. The remaining switches operating based on the clock phases Φ₂, Φ₃ and Φ₄ are in the OPEN state. In the CLOSED state, the switch 530A connects drain terminal and gate terminal of the first MOSFET 505. The drain terminal and the gate terminal when shorted, pushes the first MOSFET 505 to operate in saturation mode where it acts as a current source. When the clock phase Φ₁ is at level ‘1’, the switch 530A is in the CLOSED state and the input current Iᵢₙ, flows into the first MOSFET 505. The second MOSFET 510, the third MOSFET 515 and fourth MOSFET 520 act as current mirrors, and generate the first output current Iₒᵤₜ₁, the second output current Iₒᵤₜ₂ and the third output current Iₒᵤₜ₃, respectively. The current outputs at each phase will have distortions due to the flicker noise. When the switch 535B is in the CLOSED state, the first output current I_{out1(Φ1)}, is coupled to the second MOSFET 510. The second MOSFET 510 gives the first output current I_{out (Φ1)}. When the switch 540C is in the CLOSED state, the second output current I_{out2(Φ1)}, is coupled to the third MOSFET 515. The third MOSFET 515 gives the second output current I_{out2(Φ1)}. Further, when the switch 545D is in the CLOSED state, the third output current I_{out3(Φ1)}, is coupled to the fourth MOSFET 520. The fourth MOSFET 520 gives the third output current I_{out3(Φ1)}.

The three output currents I_{out1(Φ1)}, I_{out2(Φ1)} and I_{out3(Φ1)} are derived based on the following equations:

I_{out1(Φ1)}=Iᵢₙ+iₙ₂−iₙ₁ (Equation 1)

I_{out2(Φ1)}=Iᵢₙ+iₙ₃−iₙ₁ (Equation 2)

I_{out3(Φ1)}=Iᵢₙ+iₙ₄−iₙ₁ (Equation 3),

where Iᵢₙ is the input current, iₙ₁ is the noise introduced by the first MOSFET 505, iₙ₂ is the noise introduced by the second MOSFET 510, iₙ₃ is the noise introduced by the third MOSFET 515 and iₙ₄ is the noise introduced by the fourth MOSFET 520.

### Case 2:

FIG. 5B is another exemplary illustration of the circuit 500, operating in clock phase Φ₂. In case 2, clock phase Φ₂ is at level ‘1’ and the remaining clock phases Φ₁, Φ₃ and Φ₄ are at level ‘0’ as indicated in FIG. 6. When the clock phase Φ₂ is at level ‘1’, the switch 530D, the switch 535A, the switch 540B and the switch 545C are in the CLOSED state. The remaining switches operating based on the clock phases Φ₁, Φ₃ and Φ₄ are in the OPEN state. In the CLOSED state, the switch 535A connects drain terminal and gate terminal of the second MOSFET 510. The drain terminal and the gate terminal when shorted, pushes the second MOSFET 510 to operate in saturation mode where it acts as a current source. When the clock phase Φ₂ is at level ‘1’, the switch 535A is in the CLOSED state and the input current flows into the second MOSFET 510. The third MOSFET 515, the fourth MOSFET 520 and first MOSFET 505, operate as current mirrors, and generate the first output current Iₒᵤₜ₁, the second output current Iₒᵤₜ₂ and the third output current Iₒᵤₜ₃ respectively. When the switch 540B is in the CLOSED state, the first output current I_{out1(Φ2)}, is coupled to the third MOSFET 515. The third MOSFET 515 gives the first output current I_{out2(Φ2)}. When the switch 545C is in the CLOSED state, the second output current I_{out2(Φ2)}, is coupled to the fourth MOSFET 520. The fourth MOSFET 520 gives the second output current I_{out2(Φ2)}. Further, when the switch 530D is in the CLOSED state, the third output current I_{out3(Φ2)}, is coupled to the first MOSFET 505. The first MOSFET 505 gives the third output current I_{out3(Φ2)}.

The three output currents I_{out1(Φ2)}, I_{out2(Φ2)} and I_{out3(Φ2)} are derived based on the following equations:

I_{out1(Φ2)}=Iᵢₙ+iₙ₃−iₙ₂ (Equation 4)

I_{out2(Φ2)}=Iᵢₙ+iₙ₄−iₙ₂ (Equation 5)

I_{out3(Φ2)}=Iᵢₙ+iₙ₁−iₙ₂ (Equation 6),

where Iᵢₙ is the input current, iₙ₁ is the noise introduced by the first MOSFET 505, iₙ₂ is the noise introduced by the second MOSFET 510, iₙ₃ is the noise introduced by the third MOSFET 515 and iₙ₄ is the noise introduced by the fourth MOSFET 520.

### Case 3:

FIG. 5C is another exemplary illustration of the circuit 500, operating in clock phase Φ₃. In case 3, clock phase Φ₃ is at level ‘1’ and the remaining clock phases Φ₁, Φ₂ and Φ₄ are at level ‘0’ as indicated in FIG. 6. When the clock phase Φ₃ is at level ‘1’, the switch 530C, the switch 535D, the switch 540A and the switch 545B are in the CLOSED state. The remaining switches operating based on the clock phases Φ₁, Φ₂ and Φ₄ are in the OPEN state. In the CLOSED state, the switch 540A connects drain terminal and gate terminal of the third MOSFET 515. The drain terminal and the gate terminal when shorted, pushes the third MOSFET 515 to operate in saturation mode where it acts as a current source. When the clock phase Φ₃is at level ‘1’, the switch 540A is in the CLOSED state and the input current Iᵢₙ flows into the third MOSFET 515. The fourth MOSFET 520, the first MOSFET 505 and second MOSFET 510, operates as current minors, and generates the first output current Iₒᵤₜ₁, the second output current Iₒᵤₜ₂ and the third output current Iₒᵤₜ₃ respectively. When the switch 545B is in the CLOSED state, the first output current I_{out1(Φ3)}, is coupled to the fourth MOSFET 520. The fourth MOSFET 520 gives the first output current I_{out1(Φ3)}. When the switch 530C is in the CLOSED state, the second output current I_{out2(Φ3)}, is coupled to the first MOSFET 505. The first MOSFET 505 gives the second output current I_{out2(Φ3)}. Further, when the switch 535D is in the CLOSED state, the third output current I_{out3(Φ3)}, is coupled to the second MOSFET 510. The second MOSFET 510 gives the third output current I_{out3(Φ3)}.

The three output currents I_{out1(Φ3)}, I_{out2(Φ3)} and I_{out3(Φ3)} are derived based on the following equations:

I_{out1(Φ3)}=Iᵢₙ+iₙ₄−iₙ₃ (Equation 7)

I_{out2(Φ3)}=Iᵢₙ+iₙ₁−iₙ₃ (Equation 8)

I_{out3(Φ3)}=Iᵢₙ+iₙ₂−iₙ₃ (Equation 9)

, where Iᵢₙ is the input current, iₙ₁ is the noise introduced by the first MOSFET 505, iₙ₂ is the noise introduced by the second MOSFET 510, iₙ₃ is the noise introduced by the third MOSFET 515 and iₙ₄ is the noise introduced by the fourth MOSFET 520.

### Case 4:

FIG. 5D is another exemplary illustration of the circuit 500, operating in clock phase Φ₄. In case 4, clock phase Φ₄ is at level ‘1’ and the remaining clock phases Φ₁, Φ₂ and Φ₃are at level ‘0’ as indicated in FIG. 6. When the clock phase Φ₄ is at level ‘1’, the switch 530B, the switch 535C, the switch 540D and the switch 545A are in the CLOSED state. The remaining switches operating based on the clock phases Φ₁, Φ₂ and Φ₃ are in the OPEN state. In the CLOSED state, the switch 545A connects drain terminal and gate terminal of the fourth MOSFET 520. The drain terminal and the gate terminal when shorted, pushes the fourth MOSFET 520 to operate in saturation mode where it acts as a current source. When the clock phase Φ₄ is at level ‘1’, the switch 545A is in the CLOSED state and the input current Iᵢₙ flows into the fourth MOSFET 520. The first MOSFET 505, the second MOSFET 520 and third MOSFET 515, operates as current minors, and generates the first output current Iₒᵤₜ₁, the second output current Iₒᵤₜ₂ and the third output current Iₒᵤₜ₃ respectively. When the switch 530B is in the CLOSED state, the first output current I_{out1(Φ4)}, is coupled to the first MOSFET 520. The first MOSFET 505 gives the first output current I_{out1(Φ4)}. When the switch 535C is in the CLOSED state, the second output current I_{out2(Φ4)}, is coupled to the second MOSFET 510. The second MOSFET 510 gives the second output current I_{out2(Φ4)}. Further, when the switch 540D is in the CLOSED state, the third output current I_{out3(Φ4)}, is coupled to the third MOSFET 515. The third MOSFET 515 gives the third output current I_{out3(Φ4)}.

The three output currents I_{out1(Φ4)}, I_{out2(Φ4)} and I_{out3(Φ4)} are derived based on the following equations:

I_{out1(Φ4)}=Iᵢₙ+iₙ₁−iₙ₄ (Equation 10)

I_{out2(Φ4)}=Iᵢₙ+iₙ₂−iₙ₄ (Equation 11)

I_{out3(Φ4)}=Iᵢₙ+iₙ₃−iₙ₄ (Equation 12)

, where Iᵢₙ is the input current, iₙ₁ is the noise introduced by the first MOSFET 505, iₙ₂ is the noise introduced by the second MOSFET 510, iₙ₃ is the noise introduced by the third MOSFET 515, and iₙ₄ is the noise introduced by the fourth MOSFET 520.

A complete chopping cycle includes all the four clock phases Φ₁, Φ₂, Φ₃, and Φ₄. To generate the current mirror outputs after employing four phase chopping scheme, an average of corresponding current outputs, obtained at different phases are calculated. On averaging, the flicker noise gets cancelled. The current minor outputs Iₒᵤₜ₁, I_{out 2} and Iₒᵤₜ₃ are derived based on the following equations:

Iₒᵤₜ₁=(I_{out1(Φ1)}+I_{out1(Φ2)}+I_{out1(Φ3)}+I_{out1(Φ4)})/4 (Equation 13)

Referring to the equations 1, 4, 7 and 10 and replacing the current outputs I_{out1(Φ1)}, I_{out1(Φ2)}, I_{out1(Φ3)} and I_{out1(Φ4)} in the equation 13, the equation 13 becomes

Iₒᵤₜ₁=Iᵢₙ+((iₙ₂−iₙ₁)+(iₙ₃−iₙ₂)+(iₙ₄−iₙ₃)+(iₙ₁−iₙ₄))/4=Iᵢₙ (Equation 14)

Iₒᵤₜ₂=(I_{out2(Φ1)}+i_{out2(Φ2)}+I_{out2(Φ3)}+I_{out2(Φ4)})/4 (Equation 15)

Referring to the equations 2, 5, 8 and 11 and replacing the current outputs I_{out2(Φ1)}, I_{out2(Φ2)}, I_{out2(Φ3)} and I_{out2(Φ4)} in the equation 15, the equation 15 becomes

Iₒᵤₜ₂=Iᵢₙ+((iₙ₃−iₙ₁)+(iₙ₄−iₙ₂)+(iₙ₁−iₙ₃)+(iₙ₂−iₙ₄))/4=Iᵢₙ (Equation 16)

Iₒᵤₜ₃=(I_{out3(Φ1)}+I_{out3(Φ2)}+I_{out3(Φ3)}+I_{out3(Φ4)})/4 (Equation 17)

Referring to the equations 3, 6, 9 and 12 and replacing the current outputs I_{out3(Φ1)}, I_{out3(Φ2)}, I_{out3(Φ3)} and I_{out3(Φ4)} in the equation 17, the equation 17 becomes

Iₒᵤₜ₃=Iᵢₙ+((iₙ₄−iₙ₁)+(iₙ₁−iₙ₂)+(iₙ₂−iₙ₃)+(iₙ₃−iₙ₄))/4=Iᵢₙ (Equation 18)

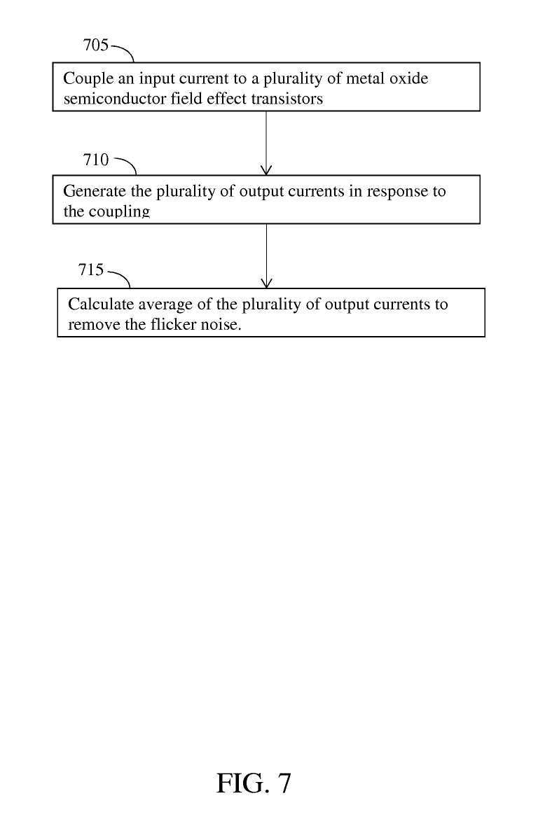

FIG. 7 is a flowchart illustrating a method employed in reducing the flicker noise in a current mirror circuit, generating a plurality of output currents.

At step 705, the input current Iᵢₙ is coupled to a plurality of metal oxide semiconductor field effect transistors (MOSFETs). In one embodiment of the present disclosure, the MOSFETs are NMOS transistors. In another embodiment of the present disclosure, the MOSFETs are PMOS transistors. The input current is coupled to one MOSFET in each phase. One of the MOSFETs, to which input is coupled, act as a current source with constant current Iᵢₙ. The remaining plurality of MOSFETs, act as current mirrors.

At step 710, a plurality of output currents is generated by the plurality of MOSFETs acting as current mirrors. The plurality of output currents is generated in response to the input coupled to one of the MOSFET. Each of the plurality of output currents in a current mirror circuit should be identical to the input current coupled to the circuit. Due to the presence of flicker noise at low frequency, the current outputs will not be identical to the input. Flicker noise can be characterized by corner frequency. MOSFETs have a corner frequency fc in MHz to GHz range and hence flicker noise is more prominent in MOSFETs than in junction field effect transistors (JFET) or bipolar transistors. Each of the plurality of MOSFETs in the current mirror circuit introduces a flicker noise. The plurality of output currents generated by the current mirrors is a function of the input current and the flicker noise of at least two MOSFETs. For reducing flicker noise a four phase chopping scheme is used. A complete chopping cycle includes four phases. In each phase, the value of each of the plurality of output currents generated keeps changing. This is because in each phase, each of the plurality of the current outputs is generated by different MOSFETs introducing different amounts of flicker noise.

At step 715, the average value of the plurality of output currents is calculated to find the low-frequency content of the output current. The calculation of the average value by the method of present disclosure includes, deriving output currents based on four phase chopping. The calculation further includes summing the output currents for each phase. When the output currents are summed, then the effect of flicker noise will get cancelled. Further, on taking the average the output currents that are identical to the input are obtained.

It is to be construed that the circuit 500 in FIG. 5, can be used to produce multiple current outputs. In some embodiments, circuit 500 includes N devices. Since there are N devices, ‘N’ phases are used to reduce the flicker noise. In existing techniques, by using a one input-one output current minor that employs chopping, ‘2N’ MOSFETs are required in order to produce n output currents. In the present disclosure, which is a one input-N output current mirror employing N phase chopping, ‘N+1’ MOS transistors are used, thereby reducing the number of transistors. In another embodiment, the chopping clock frequency selected is at least twice flicker noise frequency in the circuit 500.

In one example, the circuit 500 can be used to drive a digital to analog converter (DAC). In general, the circuit 500 can be used for low frequency applications requiring multiple current inputs. For example, the circuit 500 can be used in an audio amplifier.

Accordingly, the present disclosure is intended to be illustrative, but not limiting, of the scope of the invention, which is set forth in the following claims.

What is claimed is:

1. A circuit for reducing flicker noise, the circuit comprising:
a first current source coupled to an input current;
a plurality of current minors to generate a plurality of output currents in response to the input current, wherein the plurality of output currents comprises the flicker noise; and
a chopping circuit to reduce the flicker noise from each of the plurality of output currents.

2. The circuit as claimed in claim 1, wherein the first current source is a metal oxide semiconductor field effect transistor (MOSFET).

3. The circuit as claimed in claim 2, wherein the MOSFET is one of an NMOS transistor and a PMOS transistor.

4. The circuit as claimed in claim 1, wherein the first current source comprises a gate terminal, a drain terminal, and a source terminal.

5. The circuit as claimed in claim 4, wherein the gate terminal and the drain terminal are shorted.

6. The circuit as claimed in claim 1, wherein each of the plurality of current mirrors comprises a metal oxide semiconductor field effect transistor (MOSFET).

7. The circuit as claimed in claim 6, wherein the MOSFET is one of an NMOS transistor and a PMOS transistor.

8. The circuit as claimed in claim 1, wherein the chopping circuit is a four phase chopping circuit.

9. The circuit as claimed in claim 8, wherein the four phase chopping circuit comprises at least four switches operational in each phase.

10. The circuit as claimed in claim 1, wherein the plurality of output currents at each phase is a function of the input current and the flicker noise of at least two metal oxide semiconductor field effect transistors.

11. A method of reducing flicker noise in a current mirror circuit, the method comprising:
electrically coupling an input current to a plurality of metal oxide semiconductor field effect transistors;
generating a plurality of output currents in response to the coupling, wherein the plurality of output currents is a function of the input current and the flicker noise of at least two of the plurality metal oxide semiconductor field effect transistors; and
calculating an average of the plurality of output currents to reduce the flicker noise.

12. The method as claimed in claim 11, wherein the plurality of metal oxide semiconductor field effect transistors are one of an NMOS transistor and a PMOS transistor.

13. The method as claimed in claim 11, wherein calculating the average of the plurality of output currents comprises:
deriving output currents based on a four phase chopping scheme; and
calculating sum of the output currents for each phase.

14. The method as claimed in claim 11, wherein calculating the average of the plurality of output currents is performed in one complete chopping cycle.

15. A circuit for reducing flicker noise, the circuit comprising:
a first metal oxide semiconductor field effect transistor (MOSFET) coupled to an input current;
a second MOSFET to generate a first output current;
a third MOSFET to generate a second output current;
a fourth MOSFET to generate a third output current; and
a four phase chopping circuit comprising a plurality of switches, wherein at least four switches are operational at each phase.

16. The circuit as claimed in claim 15, wherein the first MOSFET, the second MOSFET, the third MOSFET, and the fourth MOSFET are one of an NMOS transistor and a PMOS transistor.

17. The circuit as claimed in claim 15, wherein the first MOSFET in conjunction with the second MOSFET, the third MOSFET, and the fourth MOSFET forms a three output current mirror circuit.

18. The circuit as claimed in claim 15, wherein the first output current, the second output current, and the third output current are a function of the input current and the flicker noise of at least two metal oxide semiconductor field effect transistors.
